(19) United States
(12) Patent Application Publication
(10) Pub. No.: US 2019/0296081 A1
(43) Pub. Date: Sep. 26, 2019

(54) SELECTOR-BASED ELECTRONIC DEVICES, INVERTERS, MEMORY DEVICES, AND COMPUTING DEVICES

(71) Applicant: INTEL CORPORATION, Santa Clara, CA (US)

(72) Inventors: Abhishek A. Sharma, Hillsboro, OR (US); Brian S. Doyle, Portland, OR (US); Ravi Pillarisetty, Portland, OR (US); Prashant Majhi, San Jose, CA (US); Elijah V. Karpov, Portland, OR (US)

(73) Assignee: INTEL CORPORATION, Santa Clara, CA (US)

(21) Appl. No.: 15/934,659

(22) Filed: Mar. 23, 2018

(51) Int. Cl. H01L 27/24; H01L 45/00; H01L 49/00; H01L 29/786; H03K 19/0944; G11C 13/00

(52) U.S. Cl. CPC H01L 27/2436; G11C 2213/79; H01L 45/06; H01L 45/146; H01L 45/144; H01L 45/143; H01L 45/148; H01L 45/14; H01L 49/003; H01L 45/147; H01L 45/1233; H01L 29/7869; H01L 29/78693; H01L 29/78684; H01L 29/78681; H03K 19/0944; G11C 13/0004; G11C 13/003; H01L 45/08

(57) ABSTRACT

Selector-based electronic devices, inverters, memory devices, and computing devices include a first selector and a second selector. The first selector and the second selector are electrically connected in series between a first voltage source terminal and a second voltage source terminal. The electronic device also includes a transistor electrically connected between an input terminal and a terminal between the first selector and the second selector.

### BACKGROUND

Complimentary Metal-Oxide-Semiconductor (CMOS) circuitry is in widespread use in integrated circuits due to its low-power characteristics and noise immunity. CMOS circuitry is created using complimentary pairs of n-type and p-type transistors.

### BRIEF DESCRIPTION OF THE DRAWINGS

FIG. 1 is a simplified cross-sectional view of an S-Shaped Negative Differential Resistance (S-NDR) device, according to some embodiments.

FIG. 2 is a simplified plot illustrating example current-voltage (IV) characteristics of the S-NDR device of FIG. 1, according to some embodiments.

FIG. 3 is a simplified schematic diagram of an inverter, according to some embodiments.

FIG. 4 is a simplified schematic diagram of a memory device according to some embodiments.

FIG. 5 is a simplified schematic diagram of a memory device, according to some embodiments.

FIG. 6 is a simplified block diagram of an array of data storage elements 460, according to some embodiments.

FIG. 7 is a simplified cross-sectional view of an electronic device according to some embodiments.

FIG. 8 illustrates an interposer that includes one or more embodiments of the disclosure.

FIG. 9 illustrates a computing device in accordance with one embodiment of the disclosure.

### DETAILED DESCRIPTION

Described herein are electronic devices including threshold switch based circuitry such as inverter cells and memory cells including, for example, a selector. In the following description, various aspects of the illustrative implementations will be described using terms commonly employed by those skilled in the art to convey the substance of their work to others skilled in the art. However, it will be apparent to those skilled in the art that the disclosure may be practiced with only some of the described aspects. For purposes of explanation, specific numbers, materials and configurations are set forth in order to provide a thorough understanding of the illustrative implementations. However, it will be apparent to one skilled in the art that the disclosure may be practiced without the specific details. In other instances, well-known features are omitted or simplified in order not to obscure the illustrative implementations.

Various operations will be described as multiple discrete operations, in turn, in a manner that is most helpful in understanding the disclosure. The order of the description, however, should not be construed to imply that these operations are necessarily order dependent. In particular, these operations need not be performed in the order of presentation.

The terms “over,” “under,” “between,” and “on,” as used herein, refer to relative positions of one material (e.g., region, structure, layer, etc.) or component with respect to one or more other materials (e.g., regions, structures, layers, etc.) or components. For example, one material disposed over, under, or on another material may be directly in contact with the other material or may have one or more intervening materials. Moreover, one material disposed between two materials may be directly in contact with the two materials or may have one or more intervening materials. Similarly, unless explicitly stated otherwise, one feature disposed between two features may be in direct contact with the adjacent features or may have one or more intervening features or materials.

Implementations of the disclosure may be formed or carried out on a substrate, such as a semiconductor substrate. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the disclosure.

CMOS circuitry typically includes complimentary pairs of n-type and p-type transistors. For example, a CMOS inverter includes two transistors, an n-type transistor and a p-type transistor, connected in series. Since transistors of different doping types are included, one of the two transistors will be formed in a well of opposite doping type to that of the surrounding substrate material. Spacing rules for semiconductor device layout set a minimum spacing around a well within which a transistor of another type may not be placed. As a result, the spacing between transistors of different doping types is greater than the spacing between transistors that are of the same type. Moreover, an entire local interconnect metal may be used up to connect a Gate Contact (GCN) and a Trench Contact (TCN).

In some embodiments, electronic devices disclosed herein overcome spacing issues of CMOS inverters. For example, selector devices may be used in inverter devices without the use of complementary transistors, which prevents the use of a well having a complementary doping type to the surrounding substrate material and thereby decreases the area of a chip occupied by the inverter. In some embodiments, selector devices are used as data storage elements.

As used herein, the terms “selector” and “selector device” refer to a two-terminal device that shows a voltage dependent volatile resistance state change. When a voltage potential across the terminals of a selector exceeds a certain value, known as the threshold voltage, the resistance of the device becomes relatively low as compared to the resistance of the device before the threshold voltage was applied thereto. The resistance of the device stays in the relatively low state so long as the voltage across the terminals is higher than a holding voltage. When the voltage across the terminals drops below the holding voltage, the device resistance goes back to an insulating/resistive resistance state. One example of a selector is an S-Shaped Negative Differential Resistance (S-NDR) device.

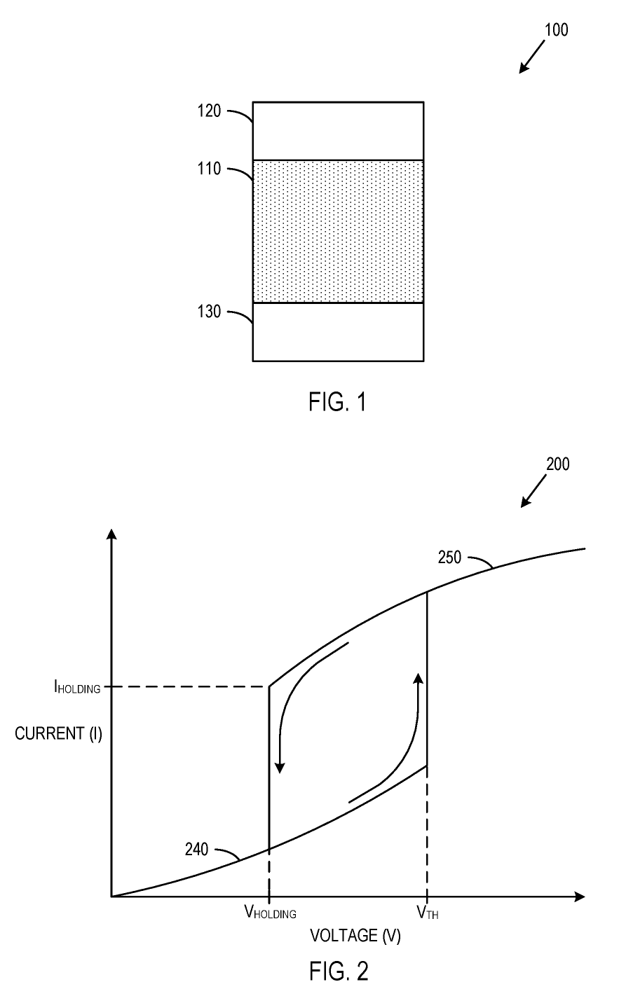

FIG. 1 is a simplified cross-sectional view of an S-NDR device 100, according to some embodiments. The S-NDR device 100 includes an NDR material 110 between a first electrically conductive region 120 and a second electrically conductive region 130 (also referred to herein sometimes as “terminals” 120, 130). The NDR material 110 may include an amorphous or poly semiconductor material, a chalcogenide, an oxide that shows metal-insulator transition behavior, or combinations thereof. By way of non-limiting example, amorphous or poly semiconductor materials that may be used in the NDR material 110 include silicon (Si), germanium (Ge), indium phosphide (InP), indium arsenide (InAs), indium gallium arsenide (InGaAs), silicon germanium (SiGe), other amorphous or poly semiconductor materials, or combinations thereof. Also by way of non-limiting example, chalcogenides that may be used in the NDR material 110 may include germanium tellurium (Ge:Te) (e.g., 10:1 to 1:10), germanium selenium (GeSe), selenium tellurium (SeTe), antimony tellurium (SbTe), silicon tellurium antimony germanium (SiTeAsGe), silicon tellurium antimony (SiTeAs), silicon tellurium (SiTe), silicon germanium tellurium (SiGeTe), other chalcogenides, or combinations thereof. As a further, non-limiting example, oxides that may be used in the NDR material 110 may include vanadium dioxide (VO₂), tantalum oxide (TaOx) (x from 1 to 2.3), niobium dioxide (NbO₂), nickel oxide (NiO), halfnium oxide (HfOx), titanium oxide (TiOx), praseodymium calcium manganese oxide (PCMO), other oxides, or combinations thereof.

The first electrically conductive region 120 and the second electrically conductive region 130 may include electrically conductive material. By way of non-limiting example, the first electrically conductive region 120 and the second electrically conductive region 130 may include titanium nitride (TiN), tantalum nitride (TaN), carbon (C), hafnium (Hf), tantalum (Ta), titanium cobalt (TiCo), tungsten (W), titanium-aluminum-carbon (TiAIC), aluminum (Al), other materials, or combinations (e.g., discrete regions, alloys, etc.) thereof.

The first electrically conductive region 120 and the second electrically conductive region 130 may be the terminals of the S-NDR device 100. In other words, different voltage potentials may be applied across the first electrically conductive region 120 and the second electrically conductive region 130 during operation of the S-NDR device 100.

FIG. 2 is a simplified plot 200 illustrating example current-voltage (IV) characteristics of the S-NDR device 100 of FIG. 1, according to some embodiments. The plot has a vertical axis that represents current (I) through the S-NDR device 100 and a horizontal axis that represents a voltage potential (V) across the terminals 120, 130 of the S-NDR device 100. The plot 200 includes a high resistance portion 240 and a low resistance portion 250. The S-NDR device 100 operates in the high resistance portion 240 prior to application of a voltage potential across the terminals 120, 130 that is greater than or equal to a threshold voltage V_{TH}. In some embodiments, this threshold voltage V_{TH} may be about 0.7 volts.

Once the threshold voltage V_{TH} is applied across the terminals 120, 130, the IV characteristics of the S-NDR device 100 are represented by the low resistance portion 250 of the plot 200, as long as the voltage potential across the terminals 120, 130 does not drop below a holding voltage potential V_{HOLDING}. A current through the S-NDR device 100 at the holding voltage V_{HOLDING} in the low resistance portion 250 of the plot may be referred to as the holding current I_{HOLDING}. Once the voltage potential across the terminals 120, 130 drops below the holding voltage V_{HOLDING} while the S-NDR device 100 is operating according to the low resistance portion 250, the S-NDR device 100 returns to the high resistance portion 240.

The dependence of the resistance state of the S-NDR device 100 between the holding voltage V_{HOLDING} and the threshold voltage V_{TH} upon the voltage potentials that have been applied across its terminals 120, 130 is referred to as “hysteresis.” The plot 200 of FIG. 2 is an illustration of a hysteresis loop. This hysteresis of the S-NDR device 100 enables the S-NDR device 100 to function as a memory cell (e.g., the different resistance states may be correlated to different logic levels), and enables the application of the S-NDR device 100 to implement an inverter without complimentary transistors.

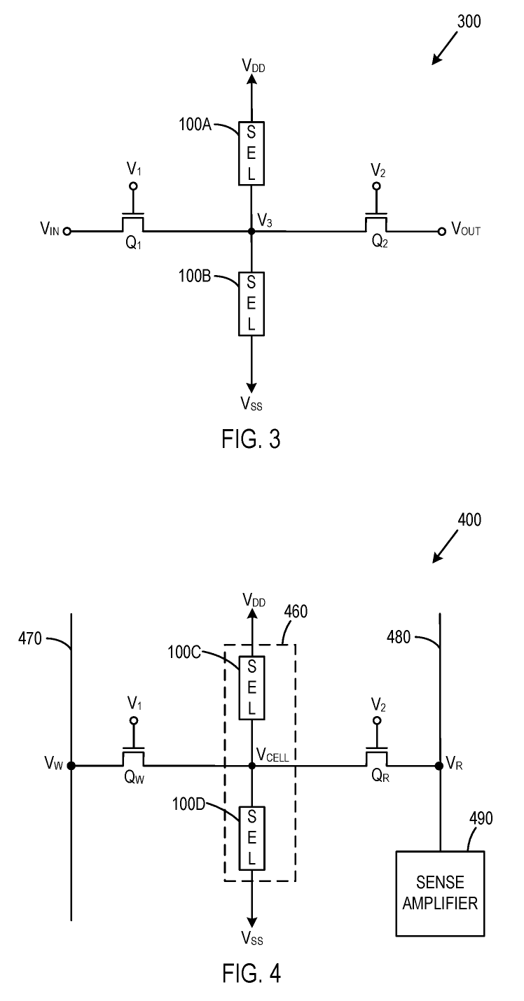

FIG. 3 is a simplified schematic diagram of an inverter 300, according to some embodiments. The inverter 300 includes a first selector 100A, a second selector 100B, a first transistor Q₁, and a second transistor Q₂. The first selector 100A and the second selector 100B are connected in series between a high power rail V_{DD} and a low power rail V_{SS} (e.g., ground, or zero volts). The first transistor Q₁ and the second transistor Q₂ are connected in series between an input V_{IN} and an output V_{OUT} of the inverter 300. Terminals V₁, V₂, and V₃ are labeled in FIG. 3 to facilitate this discussion. The terminal V₁ is electrically connected to a gate of the first transistor Q₁. The terminal V₂ is electrically connected to a gate of the second transistor Q₂. The terminal V₃ is electrically connected between the first selector 100A and the second selector 100B, and also between the first transistor Q₁ and the second transistor Q₂.

In operation, an input voltage may be applied to V_{IN}. By way of non-limiting example, the input voltage may be a logic level high or a logic level low. While the input voltage is applied to V_{IN}, the first transistor Q₁ may be turned on by applying an appropriate voltage to V₁. As a result, the first transistor will conduct, and the voltage potential at V₃ will be driven to about the same level as the input voltage at V_{IN}.

If the input voltage is a logic level high, the voltage drop across the first selector 100A may be relatively small (e.g., less than the holding voltage V_{HOLDING}) and the voltage drop across the second selector 100B may be relatively large (e.g., larger than the threshold voltage V_{TH}). As a result, the first selector 100A will operate in the high resistance state and the second selector 100B will operate in the low resistance state. The first transistor Q₁ may be turned off by applying the appropriate voltage to V₁, and the voltage at V₃ may float to a value between the holding voltage V_{HOLDING} and the threshold voltage V_{THRESHOLD}. Since the first selector 100A is operating in the high resistance state and the second selector 100B is operating in the low resistance state, the voltage potential at V₃ will be closer to V_{SS} than to V_{DD} (i.e., corresponding to a logic level low). To output this logic level low voltage potential to V_{OUT}, the second transistor Q₂ is turned on by applying an appropriate voltage potential to V₂. As a result, the second transistor Q₂ conducts the logic level low voltage potential from V₃ to V_{OUT}, and the logic level low is output to V_{OUT}. This is what is expected from an inverter, to output a logic level low in response to an input of a logic level high.

If, on the other hand, the input voltage is a logic level low, the voltage drop across the first selector 100A may be relatively large (e.g., larger than the threshold voltage V_{TH}) and the voltage drop across the second selector 1006 may be relatively small (e.g., smaller than the holding voltage V_{HOLDING}). As a result, the first selector 100A will operate in the low resistance state and the second selector 1006 will operate in the high resistance state. The first transistor Q₁ may be turned off by applying the appropriate voltage to V₁, and the voltage at V₃ may float to a value between the holding voltage V_{HOLDING} and the threshold voltage V_{THRESHOLD}. Since the first selector 100A is operating in the low resistance state and the second selector 1006 is operating in the high resistance state, the voltage potential at V₃ will be closer to V_{DD} than to V_{SS} (i.e., corresponding to a logic level high). To output this logic level high voltage potential to V_{OUT}, the second transistor Q₂ is turned on by applying an appropriate voltage potential to V₂. As a result, the second transistor Q₂ conducts the logic level high voltage potential from V₃ to V_{OUT}, and the logic level high is output to V_{OUT}. This is also what is expected from an inverter, to output a logic level high in response to an input of a logic level low.

Assuming that the threshold voltage V_{TH} of the first selector 100A and the second selector 100B is around 0.7 volts, example values for V_{SS} and V_{DD} may be selected such that a voltage potential difference between V_{DD} and V_{SS} is around one volt (1 V) (e.g., V_{SS}=0 V and V_{DD}=1 V). Also, it should be noted that the first transistor Q₁ should be turned off before the second transistor Q₂ is turned on to provide the voltage potential at V₃ to V_{OUT} in order to prevent the input V_{IN} from shorting to the output V_{OUT}.

Since the selectors 100A, 100B function as complementary elements of the inverter 300, rather than complementarily doped transistors, no well is used in the inverter (i.e., the first transistor Q1 and the second transistor Q2 may both be of the same doping type (n-MOS or p-MOS)). As a result, scaling may be improved by greater than two times as compared to complementary transistor based CMOS inverters. Also, the inverter 300 enjoys reduced coupling capacitance between the input V_{IN} and the output V_{OUT} as compared to coupling capacitance of complementary transistor based CMOS inverters because the input V_{IN} and the output V_{OUT} are buffered by diffusion capacitances of the first transistor Q1 and the second transistor Q2 instead of by a large gate capacitance. Furthermore, there may be shared diffusion and contact.

Moreover, the transistor saturation current holds the selectors 100A, 100B just at the holding voltage V_{HOLDING}. As a result, whichever of the selectors 100A, 100B is in the low resistance state will stay in the low resistance state, but will leak very little current. This is because the holding voltage V_{HOLDING} is relatively low (e.g., around 200 millivolts). This concept is similar to a capacitor holding charge, and thus a state. Also, these selectors 100A, 100B are more scalable than capacitors, and thus consume less chip area than capacitors.

In some embodiments, the selectors 100A, 100B may be implemented in the backend (i.e., in an interlayer dielectric on a frontend device layer of a semiconductor device). In such embodiments, the transistors Q₁, Q₂ may be implemented in the backend or in the frontend. By way of non-limiting example, the transistors Q₁, Q₂ may include a frontend silicon (Si), silicon germanium (SiGe), or germanium (Ge) channel transistors. Also by way of non-limiting example, the transistors Q₁, Q₂, may include backend transistors with channels made of zinc oxide (ZnO), indium oxide (InOx), indium tin oxide (ITO), aluminum zinc oxide (AZO), indium zinc oxide (IZO), indium gallium zinc oxide (IGZO), gallium zinc oxide (GZO), tin oxide (SnO), cobalt oxide (CoO), a copper oxide (CuO or Cu₂O), titanium oxide (TiOx), silicon germanium (SiGe), indium gallium arsenide (InGaAs), indium phosphide (InP), gallium nitride (GaN), aluminum gallium nitride (AlGaN), other channel materials, or combinations thereof. In some embodiments, the channel material may include a comprises a poly, amorphous, or single crystal material. In some embodiments, the selectors 100A, 100B may be implemented in the frontend, and the transistors Q₁, Q₂ may be implemented in the frontend or the backend.

FIG. 4 is a simplified schematic diagram of a memory device 400 according to some embodiments. The memory device includes a data storage element 460, a write bit line 470, a read bit line 480, a sense amplifier 490, a write access transistor Q_{W}, and a read access transistor Q_{R}. The data storage element 460 includes a first selector 100C and a second selector 100D operably coupled in series between a high power rail V_{DD} and a low power rail V_{SS}. The write access transistor Q_{W} and the read access transistor Q_{R} are operably connected in series between the write bit line 470 and the read bit line 480. Terminals V_{W}, V_{R}, V_{CELL} are labeled in FIG. 3 to facilitate this discussion. The terminal V₁ is electrically connected to a gate of the write access transistor Q_{W}. The terminal V₂ is electrically connected to a gate of the read access transistor Q_{R}. The terminal V_{CELL} is electrically connected between the first selector 100C and the second selector 100D, and also between the write access transistor Q_{W} and the read access transistor Q_{R}.

The data storage element 460 is configured to operate in different states correlated to the resistance states of the first selector 100C and the second selector 100D. For example, a first state of the data storage element 460 may correspond to the first selector 100C operating in a high resistance state and the second selector 100D operating in a low resistance state. A second state of the data storage element 460 may correspond to the first selector 100C operating in a low resistance state and the second selector 100D operating in a high resistance state. The first state and the second state of the data storage element may correspond to a first logic level and a second logic level, respectively (e.g., the first state may correspond to a logic level “1” and the second state may correspond to a logic level “0,” or vice versa).

In operation, in order to place the data storage element 460 in the first state (e.g., a logic level “1”), the write bit line 470 may be biased to a high logic level (e.g., close to V_{DD}), and the write access transistor Q_{W} may be turned on (using an appropriate value for V₁) while the read access transistor Q_{R} is off. The write access transistor Q_{W} may conduct the logic level high from V_{W} to V_{CELL} when the write access transistor Q_{W} is switched on. As a result, the first selector 100C may experience a relatively low voltage potential difference across its terminals while the second selector 100D may experience a relatively high voltage potential difference across its terminals. Accordingly, the first selector 100C may operate in the high resistance state and the second selector 100D may operate in the low resistance state responsive to the logic level high at V_{CELL}. The write transistor Q_{W} may be switched off (e.g., using an appropriate voltage at V₁). Since the resistance of the first selector 100C is greater than the resistance of the second selector 100D, the voltage level at V_{CELL} will float closer to V_{SS} than to V_{DD}.

In order to place the data storage element 460 in the second state (e.g., a logic level “0”), the write bit line 470 may be biased to a low logic level (e.g., close to V_{SS}), and the write access transistor Q_{W} may be turned on (using an appropriate value for V₁) while the read access transistor Q_{R} is off. The write access transistor Q_{W} may conduct the logic level low from V_{W} to V_{CELL} when the write access transistor Q_{W} is switched on. As a result, the first selector 100C may experience a relatively high voltage potential difference across its terminals while the second selector 100D may experience a relatively low voltage potential difference across its terminals. Accordingly, the first selector 100C may operate in the low resistance state and the second selector 100D may operate in the high resistance state responsive to the logic level low at V_{CELL}. The write transistor Q_{W} may be switched off (e.g., using an appropriate voltage at V₁). Since the resistance of the first selector 100C is less than the resistance of the second selector 100D, the voltage level at V_{CELL} will float closer to V_{DD} than to V_{SS}.

In order to detect (read) which of the first state or the second state the data storage element 460 is in (e.g., which of a logic level “1” or a logic level “0” has been stored to the data storage element 460), the read access transistor Q_{R} may be turned on (while the write access transistor Q_{W} is turned off) to conduct the voltage level at V_{CELL} to the sense amplifier 490. In some embodiments, the sense amplifier 490 may detect a voltage potential at V_{R} to determine which of the first state or the second state the data storage element 460 is in. In some embodiments, V_{R} may be biased (e.g., by the read bit line 480) to a voltage potential level that is about halfway between V_{DD} and V_{SS}, and the sense amplifier may determine which state the data storage element 460 is in by detecting whether current flows into or out of V_{CELL} from the read bit line 480 when the read access transistor Q_{R} is turned on (e.g., the first state corresponds to current flowing into V_{CELL} from the read bit line 480 and the second state corresponds to current flowing out of V_{CELL} to the read bit line 480).

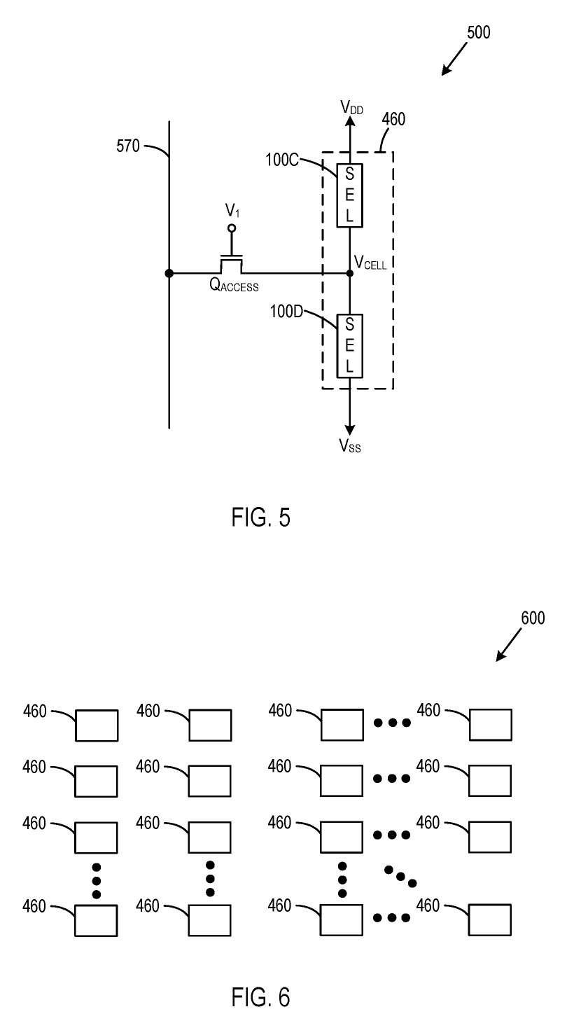

FIG. 5 is a simplified schematic diagram of a memory device 500, according to some embodiments. The memory device 500 includes a data storage element 460 as discussed above with reference to FIG. 4. The memory device 500 also includes a bit line 570 and an access transistor Q_{ACCESS}. The access transistor Q_{ACCESS} is operably coupled between the bit line 570 and a cell voltage terminal V_{CELL} between selectors 100C and 100D of the data storage element 460.

Operation of the memory device 500 may be similar to that of the memory device 400 of FIG. 4 except that only a single bit line 570 and a single access transistor Q_{ACCESS} are used for the write and read operations. To write to the data storage element 460, a low or high logic level may be applied to the bit line 570, and the access transistor Q_{ACCESS} may be turned on (e.g., using an appropriate voltage at V₁) until the data storage element 460 operates in the desired state. To then read the data stored on the data storage element 460, a sense amplifier (not shown, but similar to the sense amplifier 490 of FIG. 4) operably coupled to the bit line 570 may detect the state of the data storage element 460 when the access transistor Q_{ACCESS} is turned on for a read operation, similarly as discussed above with respect to the read access transistor Q_{R} of FIG. 4.

Since only a single transistor Q_{ACCESS} and a single bit line 570 are used to access the data storage element 460 in FIG. 5, the total chip area, and an amount of conductive material for bit lines and contacts may be reduced. Accordingly, the memory device 500 of FIG. 5 may result in higher density on a chip and have less parasitic capacitance (and higher operational speed) as compared to the memory device 400 of FIG. 4.

FIG. 6 is a simplified block diagram of an array 600 of data storage elements 460, according to some embodiments. Although only a single data storage element 460 is shown in each of the memory device 400 of FIG. 4 and the memory device 500 of FIG. 5, it is contemplated that the memory device 400 and the memory device 500 may include arrays 600 of data storage elements 460, as illustrated in FIG. 6. Although the data storage elements 460 of FIG. 6 are arranged in a two-dimensional arrangement, it is contemplated that the array 600 may be arranged in various different one, two, or even three dimensional arrangements. By way of non-limiting example, the array 600 may include a cross-point array.

Also, similarly as discussed above with reference to the inverter 300 of FIG. 3, the selectors 100C, 100D of the data storage elements 460 may be implemented in the backend, the frontend, or a combination thereof. Moreover, access transistors (e.g., Q_{W}, Q_{R}, Q_{ACCESS}) used to access the data storage elements 460 may be implemented in the frontend, in the backend, or a combination thereof.

The selectors 100C, 100D of the data storage elements 460 may be scaled to a relatively small size, as compared to capacitors (e.g., capacitors of a Dynamic Random Access Memory (DRAM) device). As a result, a memory device including the array 600 may be relatively dense, as compared to a capacitive memory device.

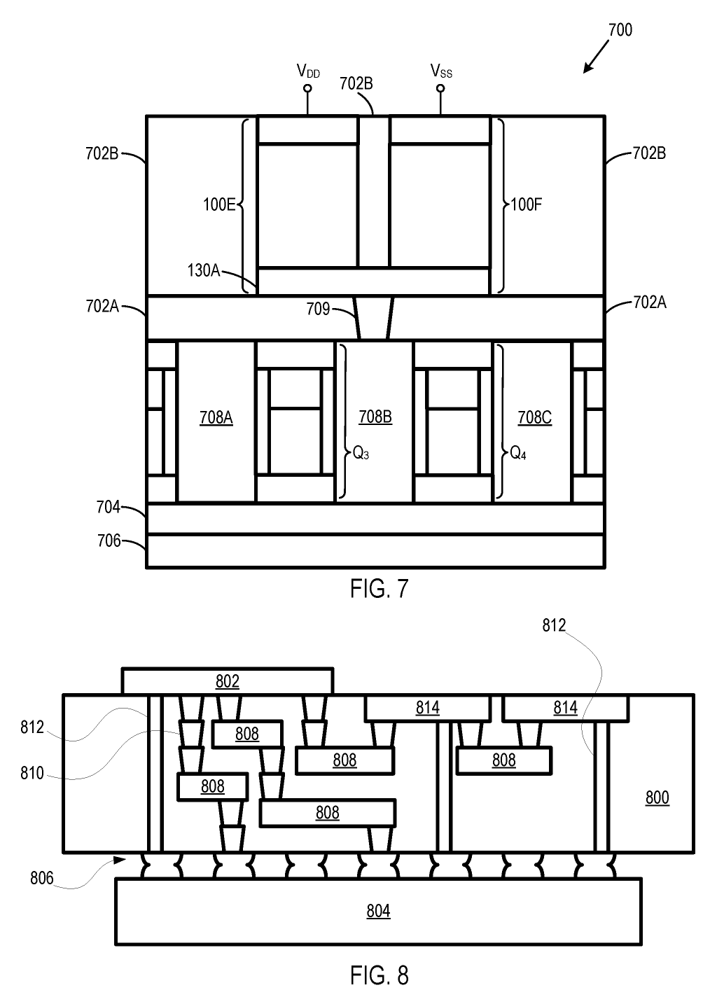

FIG. 7 is a simplified cross-sectional view of an electronic device 700 according to some embodiments. The electronic device 700 includes a first selector 100E and a second selector 100F. In some embodiments, the first selector 100E and the second selector 100F may share a common bottom terminal 130A. The electronic device 700 also includes a first transistor Q₃ and a second transistor Q₄. The electronic device 700 further includes contacts 708A, 708B, and 708C.

In some embodiments, the electronic device 700 corresponds to the inverter 300 of FIG. 3. In such embodiments, the first selector 100E, the second selector 100F, the first transistor Q₃, and the second transistor Q₄ correspond to the first selector 100A, the second selector 100B, the first transistor Q₁, and the second transistor Q₂, respectively, of FIG. 3. Also, contact 708A corresponds to V_{IN} of FIG. 3, contact 708B corresponds to V₃ of FIG. 3, and contact 708C corresponds to V_{OUT} of FIG. 3.

In some embodiments, the electronic device 700 corresponds to the memory device 400 of FIG. 4. In such embodiments, the first selector 100E, the second selector 100F, the first transistor Q₃, and the second transistor Q₁ correspond to the first selector 100C, the second selector 100D, the write access transistor Q_{W}, and the read access transistor Q_{R}, respectively, of FIG. 4. Also, contact 708A corresponds to V_{W} of FIG. 4, contact 708B corresponds to V_{CELL} of FIG. 4, and contact 708C corresponds to V_{R} of FIG. 4.

In some embodiments, the electronic device 700 corresponds to the memory device 500 of FIG. 5. In such embodiments, the first selector 100E, the second selector 100F, and the first transistor Q₃ correspond to the first selector 100C, the second selector 100D, and the write transistor Q_{ACESS}, respectively, of FIG. 5. Also, contact 708A corresponds to the bit line 570 of FIG. 5, and contact 708B corresponds to V_{CELL} of FIG. 5.

In some embodiments, the electronic device 700 also includes a substrate. The substrate may include an oxide 706 (e.g., an oxide of a SOI substrate). The electronic device may also include channel material 704 on the oxide 706. The contacts 708A, 708B, and 708C and the transistors Q₃, Q₄ may be formed on the ADM 704. The electronic device 700 may further include a first interlayer dielectric 702A and a second interlayer dielectric 702B (the first interlayer dielectric 702A and the second interlayer dielectric 702B may include the same or different materials). The first interlayer dielectric 702A may be formed on the contacts 708A, 708B, and 708C and the transistors Q₃, Q₄. The electronic device 700 may further include a via 709 including electrically conductive material. The via 709 is formed through the first interlayer dielectric 702A to electrically connect the via 709 to the contact 708B. The common bottom terminal 130A may be formed on the via 709 to electrically connect the common bottom terminal 130A to the via 709. The remainder of the first selector 100E and the second selector 100F may be formed on the common bottom terminal 130A, and the second interlayer dielectric 702B may be formed on the first interlayer dielectric 702A.

The inverter 300 (FIG. 3), the memory device 400 (FIG. 4), the memory device 500 (FIG. 5), the array 600 (FIG. 6), and the electronic device 700 (FIG. 3) include transistors. In some embodiments, a plurality of transistors, such as metal-oxide-semiconductor field-effect transistors (MOSFET or simply MOS transistors), may be fabricated on a substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode is formed on the gate dielectric and may consist of at least one P-type workfunction metal or N-type workfunction metal, depending on whether the transistor is to be a PMOS or an NMOS transistor. In some implementations, the gate electrode may consist of a stack of two or more metals, where one or more metals are workfunction metals and at least one metal is a fill metal. Further metals may be included for other purposes, such as a barrier material.

For a PMOS transistor, metals that may be used for the gate electrode include, but are not limited to, ruthenium, palladium, platinum, cobalt, nickel, and conductive metal oxides, e.g., ruthenium oxide. A p-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An n-type metal will enable the formation of an NMOS gate electrode with a workfunction that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may include a combination of U-shaped structures and planar, non-U-shaped structures. For example, the gate electrode may consist of one or more U-shaped metals formed atop one or more planar, non-U-shaped materials.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. In further embodiments, one or more metals and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

FIG. 8 illustrates an interposer 800 that includes one or more embodiments of the disclosure. The interposer 800 is an intervening substrate used to bridge a first substrate 802 to a second substrate 804. The first substrate 802 may be, for instance, an integrated circuit die. The second substrate 804 may be, for instance, a memory module, a computer motherboard, or another integrated circuit die. Generally, the purpose of an interposer 800 is to spread a connection to a wider pitch or to reroute a connection to a different connection. For example, an interposer 800 may couple an integrated circuit die to a ball grid array (BGA) 806 that can subsequently be coupled to the second substrate 804. In some embodiments, the first and second substrates 802/804 are attached to opposing sides of the interposer 800. In other embodiments, the first and second substrates 802/804 are attached to the same side of the interposer 800. And in further embodiments, three or more substrates are interconnected by way of the interposer 800.

The interposer 800 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 808 and vias 810, including but not limited to through-silicon vias (TSVs) 812. The interposer 800 may further include embedded devices 814, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 800.

In accordance with embodiments of the disclosure, apparatuses or processes disclosed herein may be used in the fabrication of interposer 800. By way of non-limiting example, one of the first substrate 802 or the second substrate 804 may include or otherwise carry the inverter 300 (FIG. 3), the memory device 400 (FIG. 4), the memory device 500 (FIG. 5), the array 600 (FIG. 6), the electronic device 700 (FIG. 7), or combinations thereof.

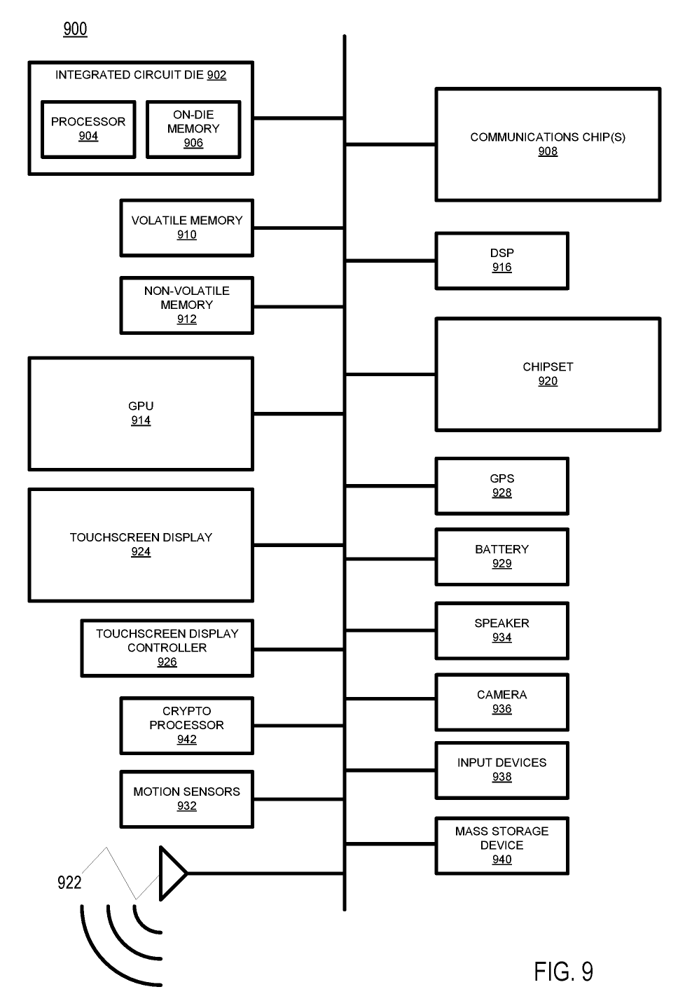

FIG. 9 illustrates a computing device 900 in accordance with one embodiment of the disclosure. The computing device 900 may include a number of components. In one embodiment, these components are attached to one or more motherboards. In an alternate embodiment, some or all of these components are fabricated onto a single system-on-a-chip (SoC) die, such as an SoC used for mobile devices. The components in the computing device 900 include, but are not limited to, an integrated circuit die 902 and at least one communications chip 908 (e.g., a communications logic unit). In some implementations the communications chip 908 is fabricated within the integrated circuit die 902 while in other implementations the communications logic unit 908 is fabricated in a separate integrated circuit chip that may be bonded to a substrate or motherboard that is shared with or electronically coupled to the integrated circuit die 902. The integrated circuit die 902 may include a processor 904 (e.g., a CPU) as well as on-die memory 906, often used as cache memory, which can be provided by technologies such as embedded DRAM (eDRAM), SRAM, or spin-transfer torque memory (STT-MRAM).

Computing device 900 may include other components that may or may not be physically and electrically coupled to the motherboard or fabricated within an SoC die. These other components include, but are not limited to, volatile memory 910 (e.g., DRAM), non-volatile memory 912 (e.g., ROM or flash memory), a graphics processing unit (GPU) 914, a digital signal processor (DSP) 916, a crypto processor 942 (e.g., a specialized processor that executes cryptographic algorithms within hardware), a chipset 920, at least one antenna 922 (in some implementations two or more antennae may be used), a display or a touchscreen display 924, a touchscreen display controller 926, a battery 929 or other power source (not shown), a power amplifier (not shown), a voltage regulator (not shown), a global positioning system (GPS) device 928, a compass (not shown), one or more motion sensors 932 (e.g., a motion coprocessor such as an accelerometer, a gyroscope, a compass, etc.), a microphone (not shown), a speaker 934, a camera 936, user input devices 938 (such as a keyboard, mouse, stylus, and touchpad), and a mass storage device 940 (such as a hard disk drive, a compact disk (CD), a digital versatile disk (DVD), and so forth). The computing device 900 may incorporate further transmission, telecommunication, or radio functionality not already described herein. In some implementations, the computing device 900 includes a radio that is used to communicate over a distance by modulating and radiating electromagnetic waves in air or space. In further implementations, the computing device 900 includes a transmitter and a receiver (or a transceiver) that is used to communicate over a distance by modulating and radiating electromagnetic waves in air or space.

The communications chip 908 may include a communications logic unit configured to transfer data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 908 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 900 may include a plurality of communications chips 908. For instance, a first communications chip 908 may be dedicated to shorter range wireless communications such as Wi-Fi, NFC, and Bluetooth and a second communications chip 908 may be dedicated to longer range wireless communications such as GPS, EDGE, GPRS, CDMA, WiMAX, LTE, Ev-DO, and others.

The processor 904 of the computing device 900 includes one or more devices that are formed in accordance with embodiments of the disclosure. By way of non-limiting example, the processor 904 may include the inverter 300 (FIG. 3), the memory device 400 (FIG. 4), the memory device 500 (FIG. 5), the array 600 (FIG. 6) the electronic device 700 (FIG. 7), or combinations thereof. The term “processor” may refer to any device or portion of a device that processes electronic data from registers and/or memory to transform that electronic data into other electronic data that may be stored in registers and/or memory.

The communications logic unit 908 may also include one or more devices that are formed in accordance with embodiments of the disclosure. By way of non-limiting example, the communications logic unit 908 may include the inverter 300 (FIG. 3), the memory device 400 (FIG. 4), the memory device 500 (FIG. 5), the array 600 (FIG. 6), the electronic device 700 (FIG. 7), or combinations thereof.

In further embodiments, another component housed within the computing device 900 may contain one or more devices that are formed in accordance with implementations of the disclosure. By way of non-limiting example, at least one of the processor 904, the on-die memory 906, the volatile memory 910, the non-volatile memory 912, the GPU 914, the touchscreen display 924, the touchscreen display controller 926, the crypto processor 942, the motion sensors 932, the antenna 922, the communications chip 908, the DSP 916, the chipset 920, the GPS 928, the battery 929, the speaker 934, the camera 936, the input devices 938, or the mass storage device 940 may include the inverter 300 (FIG. 3), the memory device 400 (FIG. 4), the memory device 500 (FIG. 5), the array 600 (FIG. 6), the electronic device 700 (FIG. 7), or combinations thereof.

In various embodiments, the computing device 900 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

### EXAMPLES

The following is a non-exhaustive list of example embodiments that fall within the scope of the disclosure. In order to avoid complexity in providing the disclosure, not all of the examples listed below are separately and explicitly disclosed as having been contemplated herein as combinable with all of the others of the examples listed below and other embodiments disclosed hereinabove. Unless one of ordinary skill in the art would understand that these examples listed below, and the above disclosed embodiments, are not combinable, it is contemplated within the scope of the disclosure that such examples and embodiments are combinable.

### Example 1

An electronic device, comprising: a first selector; a second selector, the first selector and the second selector electrically connected in series between a first voltage source terminal and a second voltage source terminal; and a transistor electrically connected between an input terminal and a terminal between the first selector and the second selector.

### Example 2

The electronic device of Example 1, wherein at least one of the first selector or the second selector comprises vanadium dioxide (VO2).

### Example 3

The electronic device of Example 1, wherein at least one of the first selector or the second selector comprises an amorphous or poly semiconductor material.

### Example 4

The electronic device of Example 3, wherein the at least one of the first selector or the second selector comprises silicon (Si), germanium (Ge), indium phosphide (InP), indium arsenide (InAs), indium gallium arsenide (InGaAs), or silicon germanium (SiGe).

### Example 5

The electronic device of Example 1, wherein at least one of the first selector or the second selector comprises a chalcogenide.

### Example 6

The electronic device of Example 5, wherein the at least one of the first selector or the second selector comprises germanium tellurium (Ge:Te) (e.g., 10:1 to 1:10), germanium selenium (GeSe), selenium tellurium (SeTe), antimony tellurium (SbTe), silicon tellurium antimony germanium (SiTeAsGe), silicon tellurium antimony (SiTeAs), silicon tellurium (SiTe), or silicon germanium tellurium (SiGeTe).

### Example 7

The electronic device of Example 1, wherein at least one of the first selector or the second selector comprises an oxide that shows metal-insulator transition behavior.

### Example 8

The electronic device of Example 7, wherein the at least one of the first selector or the second selector comprises tantalum oxide (TaOx) (x from 1 to 2.3), niobium dioxide (NbO2), nickel oxide (NiO), halfnium oxide (HfOx), titanium oxide (TiOx), or praseodymium calcium manganese oxide (PCMO).

### Example 9

The electronic device according to any one of Examples 1-8, wherein at least one of the first selector or the second selector is located within an interlayer dielectric (ILD).

### Example 10

The electronic device according to any one of Examples 1-9, wherein the transistor is located within an interlayer dielectric (ILD).

### Example 11

The electronic device according to any one of Examples 1-10, wherein the transistor comprises a channel material including at least one of zinc oxide (ZnO), indium oxide (InOx), indium tin oxide (ITO), aluminum zinc oxide (AZO), indium zinc oxide (IZO), indium gallium zinc oxide (IGZO), gallium zinc oxide (GZO), tin oxide (SnO), cobalt oxide (CoO), a copper oxide (CuO or Cu2O), titanium oxide (TiOx), silicon germanium (SiGe), indium gallium arsenide (InGaAs), indium phosphide (InP), gallium nitride (GaN), or aluminum gallium nitride (AlGaN).

### Example 12

The electronic device of Example 11, wherein the channel material comprises a poly, amorphous, or single crystal material.

### Example 13

The electronic device according to any one of Examples 1-12, further comprising another transistor operably coupled between an output terminal and the terminal between the first selector and the second selector.

### Example 14

The electronic device of Example 13, further comprising an inverter comprising the first selector, the second selector, the transistor and the another transistor.

### Example 15

The electronic device according to any one of Examples 1-13, further comprising an inverter comprising the first selector, the second selector, and the transistor.

### Example 16

The electronic device of Example 15, further comprising a read access transistor operably coupled between a read bit line and the terminal between the first selector and the second selector.

### Example 17

An inverter, comprising: a first selector and a second selector operably coupled in series between a first voltage source terminal and a second voltage source terminal; and a first transistor and a second transistor operably coupled in series between an input terminal and an output terminal, a common terminal between the first transistor and the second transistor operably coupled between the first selector and the second selector; wherein: the first transistor is configured to conduct a logic level voltage potential applied to the input terminal from the input terminal to the common terminal during electrical isolation of the common terminal from the output terminal by the second transistor; and the second transistor is configured to conduct an inverse of the logic level voltage potential from the common terminal to the output terminal during electrical isolation of the common terminal from the input terminal by the first transistor.

### Example 18

The inverter of Example 17, wherein the first transistor is of a same doping type as a doping type of the second transistor.

### Example 19

The inverter according to any one of Examples 17 and 18, wherein at least one of the first selector, the second selector, the first transistor, or the second transistor is formed in an interlayer dielectric (ILD).

### Example 20

A memory device, comprising: at least one memory cell including a first selector and a second selector operably coupled in series between a first voltage source terminal and a second voltage source terminal; and an access transistor configured to selectively operably couple a bit line to a terminal between the first selector and the second selector.

### Example 21

The memory device of Example 20, wherein the access transistor comprises a write access transistor and the bit line comprises a write bit line, the memory device further comprising a read access transistor configured to selectively operably couple a read bit line to the terminal between the first selector and the second selector.

### Example 22

The memory device of Example 21, wherein the write access transistor and the read access transistor are both of a same doping type.

### Example 23

The memory device according to any one of Examples 20-22, wherein the at least one memory cell comprises an array of memory cells.

### Example 24

A computing device, comprising: a first selector electrically connected to a first voltage source terminal; a second selector electrically connected to a second voltage source terminal, the first selector and the second selector each electrically connected to a common terminal; and at least one transistor configured to selectively electrically connect the common terminal to at least one input terminal.

### Example 25

The computing device of Example 24, further comprising: a processor mounted on a substrate; a memory unit capable of storing data; a graphics processing unit; an antenna within the computing device; a display on the computing device; a power amplifier within the processor; and a voltage regulator within the processor; wherein at least one of the processor, the memory unit, the graphics processing unit, the antenna, the display, the power amplifier, or the voltage regulator includes the first selector, the second selector, and the at least one transistor.

### Example 26

A method of forming at least a portion of the electronic device according to any one of Examples 1-16.

### Example 27

A means for forming at least a portion of the electronic device according to any one of Examples 1-16.

### Example 28

A method of operating the electronic device according to any one of Examples 1-16.

### Example 29

A means for operating the electronic device according to any one of Examples 1-16.

### Example 30

A method of forming at least a portion of the inverter according to any one of Examples 17-19.

### Example 31

A means for forming at least a portion of the inverter according to any one of Examples 17-19.

### Example 32

A method of operating the inverter according to any one of Examples 17-19.

### Example 33

A means for operating the inverter according to any one of Examples 17-19.

### Example 34

A method of forming at least a portion of the memory device according to any one of Examples 20-23.

### Example 35

A means for forming at least a portion of the memory device according to any one of Examples 20-23.

### Example 36

A method of operating the memory device according to any one of Examples 20-23.

### Example 37

A means for operating the memory device according to any one of Examples 20-23.

### Example 38

A method of forming at least a portion of the computing device according to any one of Examples 24 and 25.

### Example 39

A means for forming at least a portion of the computing device according to any one of Examples 24 and 25.

### Example 40

A method of operating the computing device according to any one of Examples 24 and 25.

### Example 41

A means for operating the computing device according to any one of Examples 24 and 25.

### Example 42

A computer-readable storage medium (e.g., a non-transitory computer-readable storage medium) having computer-readable instructions stored thereon, the computer-readable instructions configured to instruct one or more processors to perform at least a portion of the method according to any one of claims 26, 28, 30, 32, 34, 36, 38, and 40.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. An electronic device, comprising:
a first selector;
a second selector, the first selector and the second selector electrically connected in series between a first voltage source terminal and a second voltage source terminal;
a transistor electrically connected between an input terminal and a terminal between the first selector and the second selector; and
another transistor coupled in series with the transistor, the another transistor positioned between an output terminal and the terminal between the first selector and the second selector, wherein the input terminal, the output terminal, and the terminal between the first selector and the second selector are different.

2. The electronic device of claim 1, wherein at least one of the first selector or the second selector comprises vanadium dioxide (VO₂).

3. The electronic device of claim 1, wherein at least one of the first selector or the second selector comprises an amorphous or poly semiconductor material.

4. The electronic device of claim 3, wherein the at least one of the first selector or the second selector comprises silicon (Si), germanium (Ge), indium phosphide (InP), indium arsenide (InAs), indium gallium arsenide (InGaAs), or silicon germanium (SiGe).

5. The electronic device of claim 1, wherein at least one of the first selector or the second selector comprises a chalcogenide.

6. The electronic device of claim 5, wherein the at least one of the first selector or the second selector comprises germanium tellurium (Ge:Te) (e.g., 10:1 to 1:10), germanium selenium (GeSe), selenium tellurium (SeTe), antimony tellurium (SbTe), silicon tellurium antimony germanium (SiTeAsGe), silicon tellurium antimony (SiTeAs), silicon tellurium (SiTe), or silicon germanium tellurium (SiGeTe).

7. The electronic device of claim 1, wherein at least one of the first selector or the second selector comprises an oxide that shows metal-insulator transition behavior.

8. The electronic device of claim 7, wherein the at least one of the first selector or the second selector comprises tantalum oxide (TaOx) (x from 1 to 2.3), niobium dioxide (NbO₂), nickel oxide (NiO), halfnium oxide (HfOx), titanium oxide (TiOx), or praseodymium calcium manganese oxide (PCMO).

9. The electronic device of claim 1, wherein at least one of the first selector or the second selector is located within an interlayer dielectric (ILD).

10. The electronic device of claim 1, wherein the transistor is located within an interlayer dielectric (ILD).

11. The electronic device of claim 1, wherein the transistor comprises a channel material including at least one of zinc oxide (ZnO), indium oxide (InOx), indium tin oxide (ITO), aluminum zinc oxide (AZO), indium zinc oxide (IZO), indium gallium zinc oxide (IGZO), gallium zinc oxide (GZO), tin oxide (SnO), cobalt oxide (CoO), a copper oxide (CuO or Cu₂O), titanium oxide (TiOx), silicon germanium (SiGe), indium gallium arsenide (InGaAs), indium phosphide (InP), gallium nitride (GaN), or aluminum gallium nitride (AlGaN).

12. The electronic device of claim 11, wherein the channel material comprises a poly, amorphous, or single crystal material.

13. (canceled)

14. The electronic device of claim 1, further comprising an inverter comprising the first selector, the second selector, the transistor and the another transistor.

15. The electronic device of claim 1, further comprising an inverter comprising the first selector, the second selector, and the transistor.

16. The electronic device of claim 15, further comprising a read access transistor operably coupled between a read bit line and the terminal between the first selector and the second selector.

17. An inverter, comprising:
a first selector and a second selector operably coupled in series between a first voltage source terminal and a second voltage source terminal; and
a first transistor and a second transistor operably coupled in series between an input terminal and an output terminal, a common terminal between the first transistor and the second transistor operably coupled between the first selector and the second selector, wherein the first transistor is between the input terminal and the common terminal, the second transistor is between the common terminal and the output terminal, and wherein the input terminal, the output terminal, and the common terminal are different;
wherein:
the first transistor is configured to conduct a logic level voltage potential applied to the input terminal from the input terminal to the common terminal during electrical isolation of the common terminal from the output terminal by the second transistor; and
the second transistor is configured to conduct an inverse of the logic level voltage potential from the common terminal to the output terminal during electrical isolation of the common terminal from the input terminal by the first transistor.

18. The inverter of claim 17, wherein the first transistor is of a same doping type as a doping type of the second transistor.

19. The inverter of claim 17, wherein at least one of the first selector, the second selector, the first transistor, or the second transistor is formed in an interlayer dielectric (ILD).

20. A memory device, comprising:
at least one memory cell including a first selector and a second selector operably coupled in series between a first voltage source terminal and a second voltage source terminal; and
write access transistor configured to selectively operably couple a write bit line to a terminal between the first selector and the second selector; and
a read access transistor coupled in series with the write access transistor, the read access transistor configured to selectively operably couple a read bit line to the terminal between the first selector and the second selector, wherein the write bit line, the read bit line, and terminal between the first selector and the second selector are different.

21. (canceled)

22. The memory device of claim 20, wherein the write access transistor and the read access transistor are both of a same doping type.

23. The memory device of claim 20, wherein the at least one memory cell comprises an array of memory cells.

24. A computing device, comprising:
a first selector electrically connected to a first voltage source terminal;
a second selector electrically connected to a second voltage source terminal, the first selector and the second selector each electrically connected to a common terminal;
a first transistor configured to selectively electrically connect the common terminal to an input terminal; and
a second transistor in series with the first transistor configured to selectively electrically connect the common terminal to an output terminal, wherein the input terminal, the output terminal, and the common terminal are different.

25. The computing device of claim 24, further comprising:
a processor mounted on a substrate;
a memory unit capable of storing data;
a graphics processing unit;
an antenna within the computing device;
a display on the computing device;
a power amplifier within the processor; and
a voltage regulator within the processor;
wherein at least one of the processor, the memory unit, the graphics processing unit, the antenna, the display, the power amplifier, or the voltage regulator includes the first selector, the second selector, the first transistor, and the second transistor.
